(19) United States
(12) Patent Application Publication
(10) Pub. No.: US 2008/0085609 A1
(43) Pub. Date: Apr. 10, 2008

(54) METHOD FOR PROTECTING HIGH-TOPOGRAPHY REGIONS DURING PATTERNING OF LOW-TOPOGRAPHY REGIONS

(76) Inventors: James E. Vasek, Austin, TX (US); Nicole R. Ellis, Austin, TX (US); Chong-Cheng Fu, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/461,033

(22) Filed: Jul. 31, 2006

(51) Int. Cl. H01L 21/31

(52) U.S. Cl. 438/780

(57) ABSTRACT

A method for protecting at least one high-topography region on a substrate having both the at least one high-topography region and the at least one low-topography region is provided. The method comprises patterning a thick photo-resist layer having a first thickness, such that the thick photo-resist layer is formed on at least a portion of only the at least one high-topography region, wherein the high-topography region comprises a plurality of semiconductor devices of a first type. The method further comprises patterning a thin photo-resist layer having a second thickness, wherein the first thickness is greater than the second thickness, such that the patterned thin photo-resist layer is formed on at least a portion of only the at least one low-topography region. The method further comprises forming a plurality of semiconductor devices of a second type in the at least the portion of the low-topography region. The method further comprises removing both the thick photo-resist layer and the thin photo-resist layer.

### BACKGROUND

The present disclosures relate to integrated circuit fabrication, and more particularly, to a method for protecting high-topography regions during patterning of low-topography regions.

A photoresist coat process generally covers low-topography regions, i.e., regions where the existing topography is approximately less than or equal to the resist thickness, such that the resist is thick enough in the various topography regions to protect them during a subsequent etch process. In cases where a resist does not sufficiently coat a high-topography region proximate a region to be patterned, breakthrough may result during the corresponding etch. The breakthrough would occur first in the high-topography region, and compromise the existing patterned circuitry in that region. Various hardmasks could be used to protect the high-topography regions from the etch; however, using such hardmasks adds complexity to the overall process.

In addition to the above, prior known methods have required additional thin film deposition and/or etching/removal steps that are not compatible with advanced technologies. For example, prior methods use a single thick resist that is not capable of patterning 130 nm-node or more advanced design rules.

Furthermore, topography differences across a chip will cause resist coverage differences depending on the planarization properties of the resist and the specific topography. Resist step coverage is poorer in regions with significant topography, for example a stack-gate or split-gate memory array, compared to relatively flat regions. In embedded memory chip layouts, for example, memory gate patterning is typically completed before the periphery logic gates are patterned. The memory gate array is then protected from further etching by the resist used for periphery patterning. Starting with the 130 nm node, the increasingly challenging periphery device design rules require more advanced lithography techniques and thinner resists. As the resist is thinned to enable periphery patterning, the resist budget in the memory array is reduced.

Accordingly, there is a need for an improved method for overcoming the problems in the art as discussed above.

### BRIEF DESCRIPTION OF THE DRAWINGS

The present invention is illustrated by way of example and not limited by the accompanying figures, in which like references indicate similar elements, and in which:

FIG. 1 is a top down view of a portion of a circuit layout of an integrated circuit yet to be formed according to one embodiment of the present disclosure;

FIG. 2 is a cross-sectional view of the portion of the circuit layout of FIG. 1, taken along line 2-2;

FIG. 3 is a cross-sectional view of the portion of the circuit layout of FIG. 2, further including a patterned photoresist for patterning semiconductor device features having a first topography, corresponding to a high-topography, within a first region of the circuit layout, and to provide a preliminary patterning within the second region;

FIG. 4 is a top down view of the portion of the circuit layout subsequent to forming of the patterned semiconductor device features within the first region of the circuit layout and the preliminary pattern within the second region, according to one embodiment of the present disclosure;

FIG. 5 is a cross-sectional view of the portion of the circuit layout of FIG. 4, taken along line 5-5 and including the patterned semiconductor device features having the first topography within a first region of the circuit layout and the preliminary pattern within the second region;

FIG. 6 is a top down view of the portion of the circuit layout subsequent to forming of a patterned thick photoresist overlying the first region of the circuit layout, with an absence of the thick photoresist overlying the preliminary pattern within the second region, according to one embodiment of the present disclosure;

FIG. 7 is a cross-sectional view of the portion of the circuit layout of FIG. 6, taken along line 7-7 and including the patterned thick photoresist overlying the first region of the circuit layout, with an absence of the thick photoresist overlying the preliminary pattern within the second region;

FIG. 8 is a cross-sectional view of the portion of the circuit layout of FIG. 7, further including a patterned photoresist for patterning semiconductor device features having a second topography, corresponding to a low-topography, within the second region of the circuit layout;

FIG. 9 is a top down view of the portion of the circuit layout subsequent to forming of the patterned semiconductor device features in the second region of the circuit layout according to one embodiment of the present disclosure;

FIG. 10 is a cross-sectional view of the portion of the circuit layout of FIG. 9, taken along line 10-10;

FIG. 11 is a cross-sectional view of a portion of a circuit layout, according to another embodiment, including a bottom anti-reflective coating (BARC) layer overlying (i) a patterned thick photoresist overlying the first region of the circuit layout and (ii) the second region; and

FIG. 12 is a cross-sectional view of the portion of the circuit layout of FIG. 11, including a patterned photoresist in the second region and overlying the BARC layer, the patterned photoresist for patterning semiconductor device features having a second topography, corresponding to a low-topography, within the second region of the circuit layout.

The use of the same reference symbols in different drawings indicates similar or identical items. Skilled artisans will also appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

The embodiments of the present disclosure provide a simplified method that uses a thicker photoresist covering a high-topography region. The thick photoresist is coated and patterned directly on the high-topography region without use of an underlying hardmask. The thick photoresist comprises a material that is inert to a subsequent thin-resist process used for patterning a low-topography region. For example, this can be achieved by sufficiently baking the thick resist or using a specific thick resist formulation. In addition, the thin resist also must be compatible with the thick resist. Furthermore, the thick resist pattern can be baked thermally or in conjunction with UV (ultra-violet radiation) exposure, i.e., a UV bake.

Several issues may arise during the thin resist coat/expose/develop process. First, the thin resist may not adhere well due to surface changes induced by the thick resist process. This adhesion can be improved by performing a thermal bake and/or a spin-on BARC coat prior to the thin resist coat/expose/develop process. Second, the thin resist may coat the thick resist non-uniformly, causing the thin resist to not adhere to the thick resist during the thin resist development step. The thin resist can be exposed in the thick resist region so that it can be completely removed, eliminating the possibility for defects caused by thin resist lift-off. Third, the thin resist and/or BARC can pile up on the thick resist sidewall, depending on the proximity of the high- and low-topography regions. Increasing the separation of these areas can improve/reduce the pile-up. These attributes are discussed further herein.

Advantages of the method according to the various embodiments may include, but are not limited to, not requiring deposition and patterning of a true hard-mask film in the high-topography region, where thermal or plasma effects associated with hard-mask film deposition, patterning, and subsequent removal may be incompatible with the circuits in the high-topography region. Another advantage may include allowing for a very thin resist to be used to pattern the low-topography region, which can improve the lithographic process window for patterning of sub-wavelength features. In one embodiment, the method enables patterning of sub-wavelength logic gates in embedded memory designs with thinner resists while preserving the memory device integrity.

FIG. 1 is a top down view of a portion of a circuit layout 10 of an integrated circuit yet to be formed according to one embodiment of the present disclosure. The portion of the circuit layout 10 includes a first region 12 and a second region 14, generally separated at a boundary 16. The first region 12 includes a region in which semiconductor device features having a first topography are yet to be formed. The second region 14 includes a region in which semiconductor device features having a second topography are yet to be formed. The second topography comprises a height that differs from a height of the first topography. In one embodiment, the first region 12 includes a region for the formation of an embedded non-volatile memory (NVM) device array and the second region 14 includes a region for the formation of peripheral devices and/or logic circuitry devices.

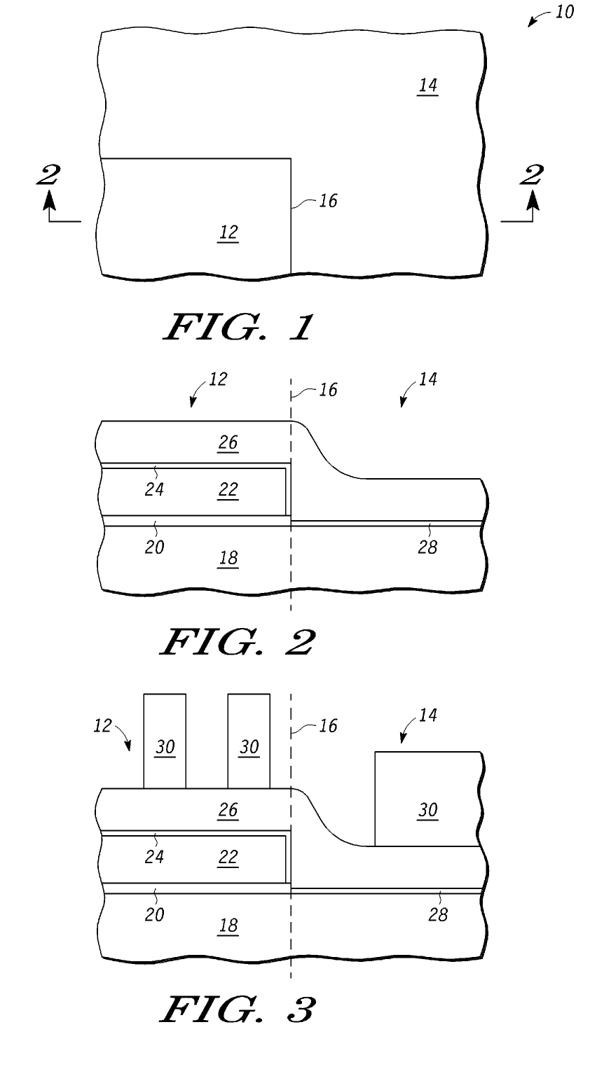

FIG. 2 is a cross-sectional view of the portion of the circuit layout 10 of FIG. 1, taken along line 2-2. The portion of the circuit layout 10 includes a substrate 18, wherein the substrate comprises any suitable substrate, including one or more isolation and/or doped regions (not shown), according to the requirements of a given semiconductor integrated circuit application. Substrate 18 may include, for example, a bulk semiconductor substrate or a semiconductor-on-insulator (SOI) substrate.

Within the first region 12, there is provided a first dielectric stack 20, a first semiconductor material layer 22, a second dielectric stack 24 and a second semiconductor material layer 26, using any suitable semiconductor processing steps. The first dielectric stack 20 is illustrated in FIG. 2 as a single layer; however, the first dielectric stack 20 can comprise more than one dielectric layer, according to the requirements of a given semiconductor device application. Overlying the first dielectric stack 20 is the first semiconductor material layer 22. While the first semiconductor material layer 22 is illustrated in FIG. 2 as a single layer, it can also comprise one or more semiconductor layers, according to the requirements of a given semiconductor device application. The second dielectric stack 24 overlies the first semiconductor material layer 22, wherein the second dielectric layer 24 may comprise one or more dielectric layers, according to the requirements of the given semiconductor device application. In addition, a portion of the second dielectric layer 24 overlies a sidewall of the first semiconductor material layer 22 proximate the boundary 16. Furthermore, in one embodiment, the first semiconductor material layer 22 and the second semiconductor material layer 26 comprise polysilicon.

Within the second region 14, there is provided another dielectric stack 28 and the second semiconductor material layer 26, using any suitable semiconductor processing steps. The dielectric stack 28 is illustrated in FIG. 2 as a single layer; however, it can comprise more than one dielectric layer, according to the requirements of a given semiconductor device application. In addition, overlying the dielectric stack 28 in the second region 14 is the second semiconductor material layer 26. While the second semiconductor material layer 26 is illustrated in FIG. 2 as a single layer, it can also comprise one or more semiconductor layers, according to the requirements of a given semiconductor device application. Furthermore, in another embodiment, the semiconductor material layer 26 in the first region 12 can comprise a different semiconductor material from the semiconductor material layer 26 in the second region 14. In yet another embodiment, the dielectric stack 28 of the second region 14 can comprise the same dielectric stack as either one of dielectric stack 20 or 24 of the first region 12.

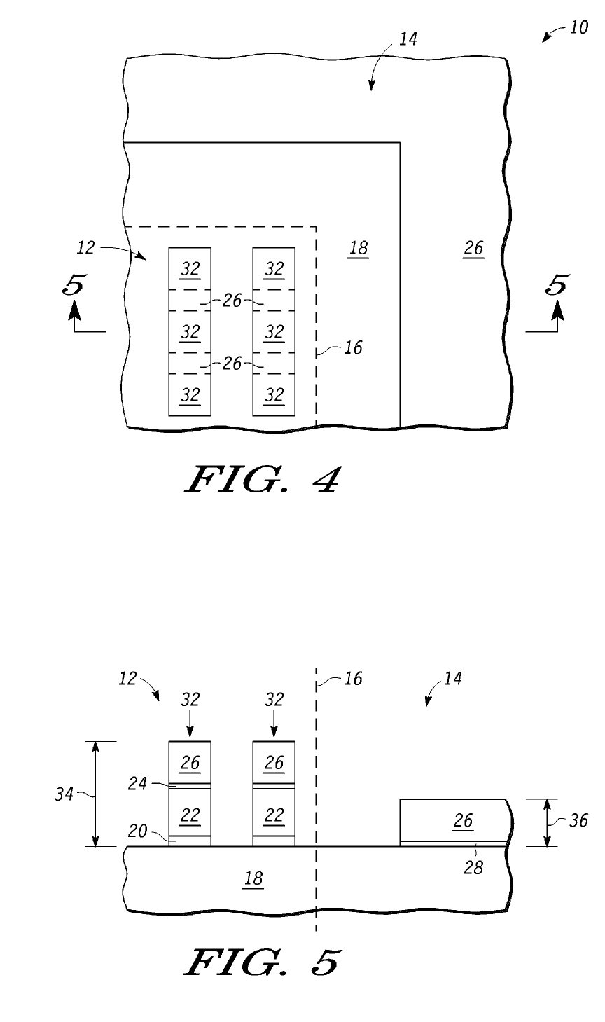

FIG. 3 is a cross-sectional view of the portion of the circuit layout of FIG. 2, further including a patterned photoresist 30. Patterned photoresist 30 provides patterning for semiconductor device features having a first topography, corresponding to a high-topography, within a first region 12 of the circuit layout. Patterned photoresist 30 also provides a preliminary patterning within the second region 14. For example, in one embodiment, the patterned photoresist 30 within the first region 12 is used to define semiconductor device features within the dielectric stacks (20,24) and semiconductor material layers (22,26) of the first region 12. In addition, the patterned photoresist 30 within the second region 14 is used to define a preliminary region of the dielectric stack 28 and semiconductor material layer 26 of the second region, the preliminary patterned region of the dielectric stack 28 and semiconductor material layer 26 of the second region 14 to be used in the forming of semiconductor device features within the second region.

FIG. 4 is a top down view of the portion of the circuit layout 10 subsequent to forming of the patterned semiconductor device features 32 within the first region 12 of the circuit layout and the preliminary pattern within the second region 14, according to one embodiment of the present disclosure. In the top down view of FIG. 4, the patterned semiconductor device features in the first region 12 include alternating regions of (i) the features 32, (ii) stacks of semiconductor material layer 26 and one or more underlying dielectric stacks (not shown), and (iii) exposed portions of substrate 18 within the first region 12. In one embodiment, features 32 represent features in the formation of NVM array devices, as may be required for a given integrated circuit application. The top down view of FIG. 4 also illustrates an exposed portion of substrate 18 and the preliminary pattern of semiconductor material layer 26 within the second region 14.

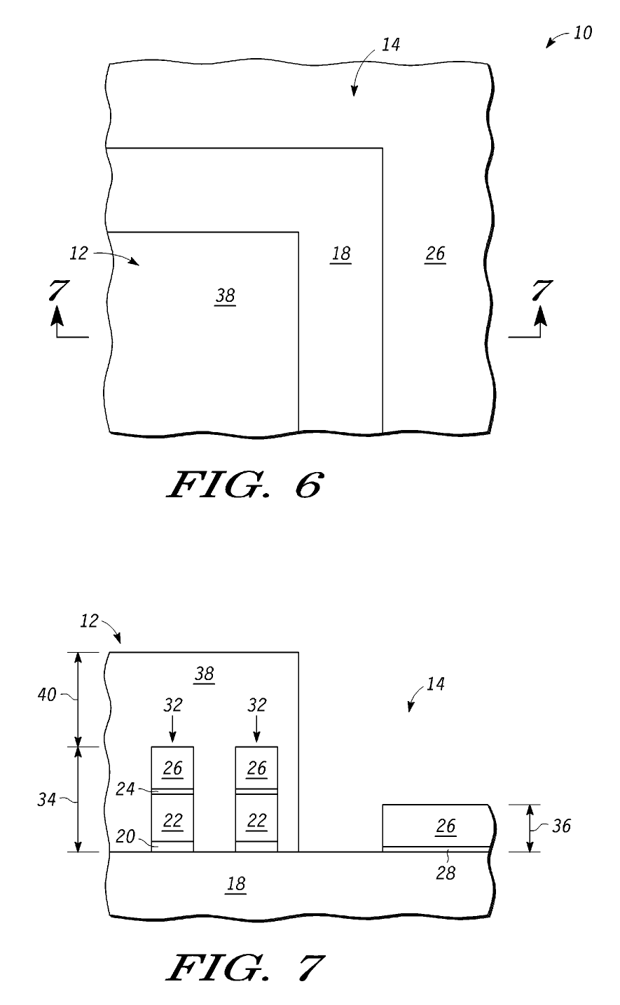

FIG. 5 is a cross-sectional view of the portion of the circuit layout of FIG. 4, taken along line 5-5 and including (i) the patterned semiconductor device features 32 having the first topography within a first region 12 of the circuit layout and (ii) the preliminary pattern within the second region 14. The patterned semiconductor device features 32 having the first topography include a height dimension indicated by reference numeral 34. The preliminary pattern within the second region 14 has a second topography that includes a height dimension, as indicated by reference numeral 36. In one embodiment, the first height dimension 34 is greater than the second height dimension 36.

FIG. 6 is a top down view of the portion of the circuit layout 10 subsequent to forming of a patterned thick photoresist 38 overlying the first region 12 of the circuit layout, with an absence of the thick photoresist overlying the preliminary pattern of layers (26,28) within the second region 14, according to one embodiment of the present disclosure. In one embodiment, thick photoresist 38 may comprise, for example, an i-line (365 nm exposure wavelength) resist. In addition, in another embodiment, the method includes applying a thermal or UV bake to harden the thick photoresist 38. The patterned thick photoresist 38 (FIG. 6) may also overlie a portion of the exposed substrate 18 (FIG. 4) within the second region 14. In other words, in one embodiment, the patterned thick photoresist 38 may extend across boundary 16 into the second region 14 by a certain amount.

FIG. 7 is a cross-sectional view of the portion of the circuit layout of FIG. 6, taken along line 7-7 and including the patterned thick photoresist 38 overlying the first region 12 of the circuit layout, with an absence of the thick photoresist overlying the preliminary pattern within the second region 14. The patterned thick photoresist 38 overlies the first region 12 and includes a height dimension above the underlying device features 32, as indicated by reference numeral 40, and an overall height dimension equal to the heights indicated by the sum of heights 34 and 40. The height dimension 40 is selected to ensure sufficient protection of the underlying semiconductor device features 32 during a patterning and etch of device features within the preliminary patterned region of the dielectric stack 28 and semiconductor material layer 26 of the second region 14, yet to be performed.

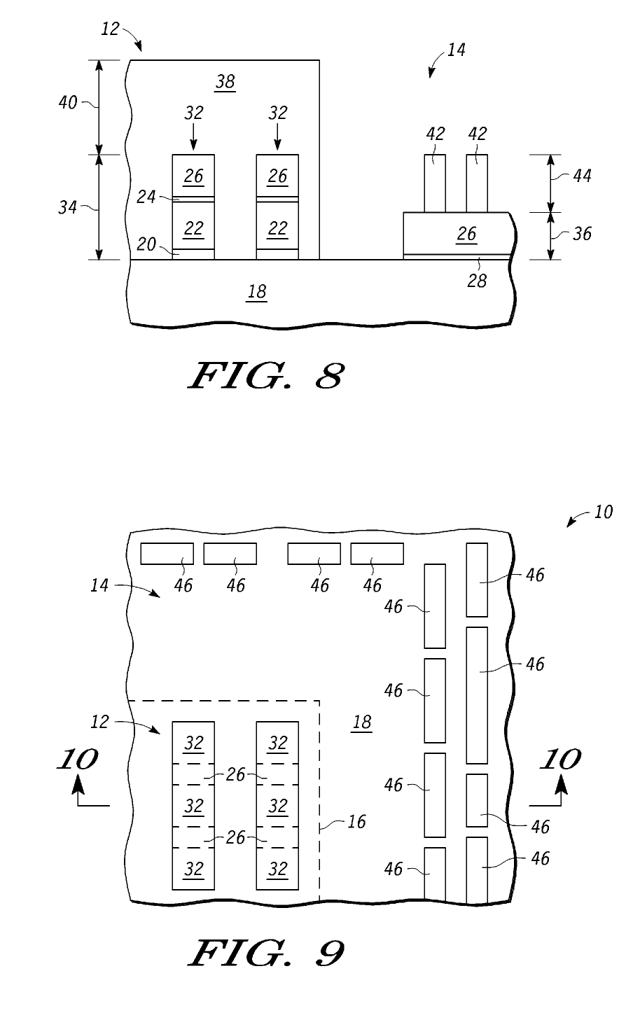

FIG. 8 is a cross-sectional view of the portion of the circuit layout 10 of FIG. 7, further including a patterned thin photoresist 42 for patterning semiconductor device features having a second topography, corresponding to a low-topography, within the second region 14 of the circuit layout. For example, in one embodiment, the patterned thin photoresist 42 within the second region 14 is used to define semiconductor device features within the dielectric stack 28 and semiconductor material layer 26 of the second region 14. The patterned thin photoresist 42 includes a height dimension above the underlying layers, as indicated by reference numeral 44.

In one embodiment, the thick photoresist layer 38 comprises a photoresist material selected to be different from a photoresist material of the thin photoresist 42. That is, photoresist 38 and photoresist 42 are selected such that during processing (i.e., depositing, exposure, and developing) of the photoresist 42, the integrity of both the photoresists are maintained. In other words, a processing of the photoresist 42 has no adverse impact on the integrity of the thick photoresist 38. In addition, the presence of the thick photoresist 38 has no adverse impact on the integrity of the photoresist 42, during a processing of photoresist 42. In another embodiment, photoresist layer 38 can comprise a photoresist suitable for 365 nm exposure wavelength (i-line), having an overall thickness on the order of five-thousand to seven-thousand (5,000-7,000) Angstroms. In addition, photoresist layer 42 can comprise a photoresist suitable for 248 nm or 193 nm exposure wavelength, having a thickness on the order of two-thousand to three-thousand (2,000-3,000) Angstroms. In a further embodiment, the thickness 44 is on the order of 2,500 Angstroms. In a still further embodiment, the thin resist over the thick resist can be exposed and removed, prior to or during the patterning of the device layers in the second region.

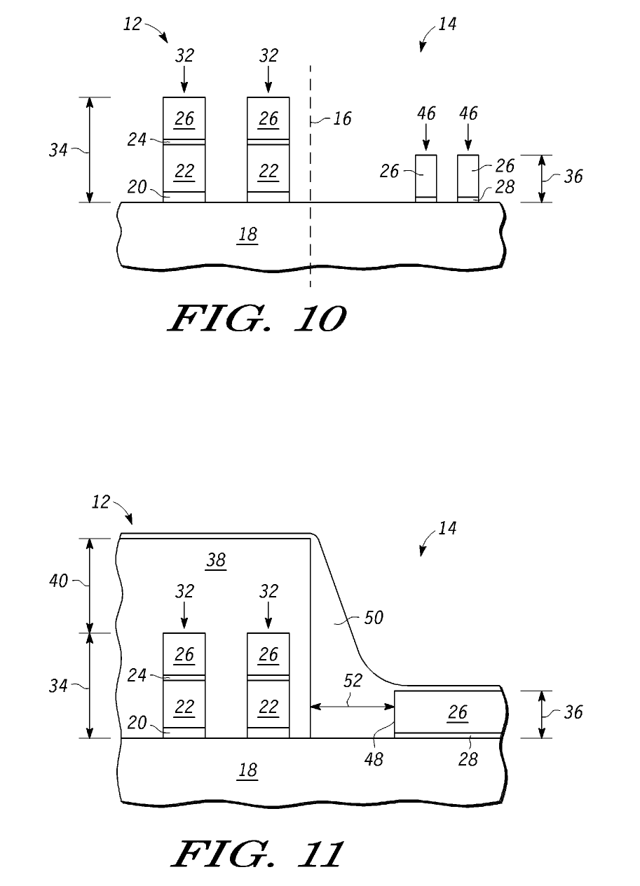

FIG. 9 is a top down view of the portion of the circuit layout 10 subsequent to forming of the patterned semiconductor device features 46 in the second region 14 of the circuit layout according to one embodiment of the present disclosure. In the top down view of FIG. 9, the patterned semiconductor device features in the second region 14 are formed by a pattern transfer etch of the patterned thin resist 42 and include regions of (i) the features 46 and (ii) exposed portions of substrate 18 within the second region 14. In one embodiment, features 46 represent features in the formation of peripheral or logic circuitry devices, as may be required for a given integrated circuit application.

Subsequent to forming the patterned semiconductor device features 46 using patterned thin resist 42, all remaining thick and thin resist is removed, for example, using a suitable common etch. As a result of concurrent removal of the thick and thin photo-resist layers in one step, no additional film deposition and/or etching processes are required. Accordingly, the number of process steps is advantageously reduced. In another embodiment, removal of the remaining thick resist may require an additional process step, for example, if it is not completely removed with the thin resist removal process.

FIG. 10 is a cross-sectional view of the portion of the circuit layout 10 of FIG. 9, taken along line 10-10. As discussed herein, the patterned semiconductor device features 32 have a first topography that includes a height dimension indicated by reference numeral 34. The patterned semiconductor device features 46 have a second topography that includes a height dimension as indicated by reference numeral 36. In one embodiment, the first height dimension 34 is greater than the second height dimension 36.

FIG. 11 is a cross-sectional view of a portion of a circuit layout 10, according to another embodiment, including a bottom anti-reflective coating (BARC) layer 50 overlying (i) a patterned thick photoresist 38 overlying the first region 12 of the circuit layout and (ii) the second region 14. FIG. 11 is similar to that as described in reference to FIGS. 4 and 5 herein, with the following differences. The preliminary pattern within the second region 14 is defined as a region of the dielectric stack 28 and semiconductor material layer 26 having a boundary or edge indicated by reference numeral 48. A boundary separation distance is created between the edge 48 of preliminary pattern region and an edge of the thick photoresist 38, as indicated by reference numeral 52. The distance 52 is selected such that subsequent to deposition of the BARC layer 50, the top surface of the deposited BARC layer 50 is substantially parallel with the top surface of the semiconductor material layer 26 in the second region 14. Deposition of BARC layer 50 substantially fills in an area overlying an exposed portion of substrate 18 between edge 48 and the edge of the thick photoresist 38. In one embodiment, BARC layer 50 comprises any suitable spin-on anti-reflective coating. Further according to the embodiments of the present disclosure, the thick resist type is matched to the thin resist type, the spin-on anti-reflection coating, and the thermal bakes to apply, for achieving optimal patterning with minimal defectivity.

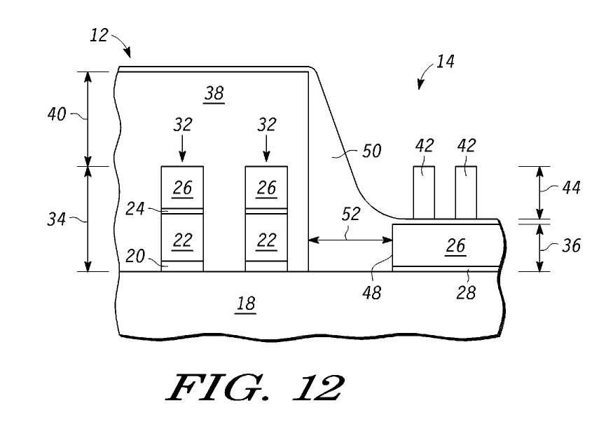

FIG. 12 is a cross-sectional view of the portion of the circuit layout of FIG. 11, including a patterned photoresist 42 in the second region 14 and overlying the BARC layer 50, the patterned photoresist 42 for patterning semiconductor device features having a second topography, corresponding to a low-topography, within the second region of the circuit layout. For example, in one embodiment, the patterned thin photoresist 42 within the second region 14 is used to define semiconductor device features within the dielectric stack 28 and semiconductor material layer 26 of the second region 14, etching through the BARC layer 50. The patterned thin photoresist 42 includes a height dimension above the underlying layers, as indicated by reference numeral 44.

In an alternate embodiment, the BARC layer 50 can be deposited directly overlying the alternating regions of (i) the features 32, (ii) stacks of semiconductor material layer 26 and one or more underlying dielectric stacks (not shown), and (iii) exposed portions of substrate 18 within the first region 12.

According to one embodiment, a method for protecting at least one high-topography region on a substrate having both the at least one high-topography region and at least one low-topography region, comprises: patterning a thick photo-resist layer having a first thickness, such that the thick photo-resist layer is formed on at least a portion of only the at least one high-topography region, wherein the high-topography region comprises a plurality of semiconductor devices of a first type; patterning a thin photo-resist layer having a second thickness, wherein the first thickness is greater than the second thickness, such that the patterned thin photo-resist layer is formed on at least a portion of only the at least one low-topography region; forming a plurality of semiconductor devices of a second type in the at least the portion of the low-topography region; and removing both the thick photo-resist layer and the thin photo-resist layer. In addition, the method further comprises hardening the thick photo-resist layer, wherein hardening the thick photo-resist layer comprises hardening the thick photo-resist layer using a thermal bake process or an ultra-violet bake process.

In another embodiment, patterning of the thin photo-resist layer comprises depositing a photo-resist material on both the thick photo-resist layer and the at least one low-topography region. In addition, the method further comprises removing the thin photo-resist layer from over the thick photo-resist layer.

According to another embodiment, the method further comprises depositing an anti-reflective layer on both the thick photo-resist layer and the at least one low-topography region prior to patterning the thin photo-resist layer. In one embodiment, the low-topography region comprises a semiconductor layer having an edge adjacent to the high-topography region, wherein the method further comprises patterning the thick photo-resist layer such that an edge of the thick photo-resist layer adjacent to the edge of the low-topography region is formed at a distance to ensure that a top surface of the anti-reflective layer is substantially parallel with a top surface of the semiconductor layer in a region overlying the semiconductor layer. The method can further comprise depositing an anti-reflective layer on both the at least one high-topography region and the at least one low-topography region prior to patterning the thick photo-resist layer and prior to patterning the thin photo-resist layer.

In yet another embodiment, the low-topography region comprises a semiconductor layer having an edge adjacent to the high-topography region, wherein the method further comprises patterning the thick photo-resist layer such that an edge of the thick photo-resist layer adjacent to the edge of the low-topography region is formed at a distance to ensure that a top surface of the thin photo-resist layer is substantially parallel with a top surface of the semiconductor layer in a region overlying the semiconductor layer.

According to another embodiment, a method for protecting at least one high-topography region on a substrate having both the at least one high-topography region and at least one low-topography region, comprises: patterning a thick photo-resist layer having a first thickness, such that the thick photo-resist layer is formed on at least a portion of only the at least one high-topography region, wherein the high-topography region comprises a plurality of semiconductor devices of a first type; hardening the thick photo-resist layer; patterning a thin photo-resist layer having a second thickness, wherein the first thickness is greater than the second thickness, such that the patterned thin photo-resist layer is formed on at least a portion of only the at least one low-topography region; forming a plurality of semiconductor devices of a second type in at least a portion of the low-topography region; and removing both the thick photo-resist layer and the thin photo-resist layer. In one embodiment, hardening the thick photo-resist layer comprises hardening the thick photo-resist layer using a thermal bake process or an ultra-violet bake process.

In another embodiment, patterning the thin photo-resist layer comprises depositing a photo-resist material on both the thick photo-resist layer and the at least one low-topography region. The method further includes removing the thin photo-resist layer from over the thick photo-resist layer. In yet another embodiment, the method further comprises depositing an anti-reflective layer on both the thick photo-resist layer and the at least one low-topography region prior to patterning the thin photo-resist layer.

According to another embodiment, a method for protecting at least one high-topography region on a substrate having both the at least one high-topography region and at least one low-topography region, comprises patterning a thick photo-resist layer having a first thickness, such that the thick photo-resist layer is formed on at least a portion of only the at least one high-topography region, wherein the high-topography region comprises a plurality of semiconductor devices of a first type; hardening the thick photo-resist layer; depositing an anti-reflective layer on both the thick photo-resist layer and the at least one low-topography region; patterning a thin photo-resist layer having a second thickness, wherein the first thickness is greater than the second thickness, such that the patterned thin photo-resist layer is formed on at least a portion of only the at least one low-topography region, wherein patterning the thin photo-resist layer comprises depositing a photo-resist material on both the thick photo-resist layer and the at least one low-topography region; removing the thin photo-resist layer from over the thick photo-resist layer; forming a plurality of semiconductor devices of a second type in at least a portion of the low-topography region; and removing both the thick photo-resist layer and the thin photo-resist layer. In one embodiment, hardening the thick photo-resist layer comprises hardening the thick photo-resist layer using a thermal bake process or an ultra-violet bake process.

In another embodiment, the low-topography region comprises a semiconductor layer having an edge adjacent to the high-topography region, wherein the method further comprises patterning the thick photo-resist layer such that an edge of the thick photo-resist layer adjacent to the edge of the low-topography region is formed at a distance to ensure that a top surface of the anti-reflective layer is substantially parallel with a top surface of the semiconductor layer in a region overlying the semiconductor layer. In another embodiment, the low-topography region comprises a semiconductor layer having an edge adjacent to the high-topography region, wherein the method further comprises patterning the thick photo-resist layer such that an edge of the thick photo-resist layer adjacent to the edge of the low-topography region is formed at a distance to ensure that a top surface of the thin photo-resist layer is substantially parallel with a top surface of the semiconductor layer in a region overlying the semiconductor layer.

Accordingly, the embodiments disclosed herein thus provide a method for patterning a thick resist followed by patterning a thin resist to enable etching of desired features while protecting high-topography regions. The thick resist provides sufficient step coverage in a high topography region that remains in place during the thin resist patterning step, and can be removed along with the thin resist. The thin resist comprises a resist that will not dissolve the thick resist pattern. In addition, the embodiments include a combination of coat, exposure and development processes to pattern both the thick and thin resists prior to etching. Furthermore, use of both a thick resist and a thin resist together in semiconductor device fabrication or manufacturing technique to protect a high-topography area while patterning a low-topography area resolves the problems discussed herein without the need for additional thin-film deposition and removal steps. Moreover, the use of a thick resist and a thin resist together, as disclosed herein, is compatible with existing lithography/etch integrations.

In the foregoing specification, the disclosure has been described with reference to the various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments. For example, while the various embodiments of the method have been described with respect to making 130 nm technology node or more advanced memory devices, the method may also be applied in various product designs resulting in high topography processing, e.g. automotive product designs, flash memory, etc. That is, the embodiments of the present disclosure can be used in NVM process technology and other process technology for embedded NVM designs, for example, in automotive products. The method according to the various embodiments furthermore provide a unique process to manufacture embedded NVM designs without added cost and complexity of additional thin film deposition and removal steps. The method may also be useful in 3D device designs with high topography. Furthermore, the periphery areas could be patterned before the memory array areas. Also, the memory array could be protected using a thick planarizing layer under the thin imaging resist.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method for protecting at least one high-topography region on a substrate having both the at least one high-topography region and at least one low-topography region, comprising:
patterning a thick photo-resist layer having a first thickness, such that the thick photo-resist layer is formed on at least a portion of only the at least one high-topography region, wherein the high-topography region comprises a plurality of semiconductor devices of a first type;
patterning a thin photo-resist layer having a second thickness, wherein the first thickness is greater than the second thickness, such that the patterned thin photo-resist layer is formed on at least a portion of only the at least one low-topography region;
forming a plurality of semiconductor devices of a second type in the at least the portion of the low-topography region; and
removing both the thick photo-resist layer and the thin photo-resist layer.

2. The method of claim 1 further comprising hardening the thick photo-resist layer.

3. The method of claim 2, wherein hardening the thick photo-resist layer comprises hardening the thick photo-resist layer using a thermal bake process or an ultra-violet bake process.

4. The method of claim 1, wherein patterning the thin photo-resist layer comprises depositing a photo-resist material on both the thick photo-resist layer and the at least one low-topography region.

5. The method of claim 4 further comprising removing the thin photo-resist layer from over the thick photo-resist layer.

6. The method of claim 1 further comprising depositing an anti-reflective layer on both the thick photo-resist layer and the at least one low-topography region prior to patterning the thin photo-resist layer.

7. The method of claim 1 further comprising depositing an anti-reflective layer on both the at least one high-topography region and the at least one low-topography region prior to patterning the thick photo-resist layer and prior to patterning the thin photo-resist layer.

8. The method of claim 1 further comprising forming at least one feature in the high-topography region.

9. The method of claim 1, wherein the plurality of semiconductor devices of the first type comprise a non-volatile memory array and the plurality of semiconductor devices of the second type comprise logic circuits.

10. The method of claim 6, wherein the low-topography region comprises a semiconductor layer having an edge adjacent to the high-topography region, further comprising patterning the thick photo-resist layer such that an edge of the thick photo-resist layer adjacent to the edge of the low-topography region is formed at a distance to ensure that a top surface of the anti-reflective layer is substantially parallel with a top surface of the semiconductor layer in a region overlying the semiconductor layer.

11. The method of claim 1, wherein the low-topography region comprises a semiconductor layer having an edge adjacent to the high-topography region, further comprising patterning the thick photo-resist layer such that an edge of the thick photo-resist layer adjacent to the edge of the low-topography region is formed at a distance to ensure that a top surface of the thin photo-resist layer is substantially parallel with a top surface of the semiconductor layer in a region overlying the semiconductor layer.

12. A method for protecting at least one high-topography region on a substrate having both the at least one high-topography region and at least one low-topography region, comprising:
patterning a thick photo-resist layer having a first thickness, such that the thick photo-resist layer is formed on at least a portion of only the at least one high-topography region, wherein the high-topography region comprises a plurality of semiconductor devices of a first type;
hardening the thick photo-resist layer;
patterning a thin photo-resist layer having a second thickness, wherein the first thickness is greater than the second thickness, such that the patterned thin photo-resist layer is formed on at least a portion of only the at least one low-topography region;
forming a plurality of semiconductor devices of a second type in at least a portion of the low-topography region; and
removing both the thick photo-resist layer and the thin photo-resist layer.

13. The method of claim 12, wherein hardening the thick photo-resist layer comprises hardening the thick photo-resist layer using a thermal bake process or an ultra-violet bake process.

14. The method of claim 12, wherein patterning the thin photo-resist layer comprises depositing a photo-resist material on both the thick photo-resist layer and the at least one low-topography region.

15. The method of claim 14 further comprising removing the thin photo-resist layer from over the thick photo-resist layer.

16. The method of claim 12 further comprising depositing an anti-reflective layer on both the thick photo-resist layer and the at least one low-topography region prior to patterning the thin photo-resist layer.

17. A method for protecting at least one high-topography region on a substrate having both the at least one high-topography region and at least one low-topography region, comprising:
patterning a thick photo-resist layer having a first thickness, such that the thick photo-resist layer is formed on at least a portion of only the at least one high-topography region, wherein the high-topography region comprises a plurality of semiconductor devices of a first type;
hardening the thick photo-resist layer;
depositing an anti-reflective layer on both the thick photo-resist layer and the at least one low-topography region;
patterning a thin photo-resist layer having a second thickness, wherein the first thickness is greater than the second thickness, such that the patterned thin photo-resist layer is formed on at least a portion of only the at least one low-topography region, wherein patterning the thin photo-resist layer comprises depositing a photo-resist material on both the thick photo-resist layer and the at least one low-topography region;
removing the thin photo-resist layer from over the thick photo-resist layer;
forming a plurality of semiconductor devices of a second type in at least a portion of the low-topography region; and
removing both the thick photo-resist layer and the thin photo-resist layer.

18. The method of claim 17, wherein hardening the thick photo-resist layer comprises hardening the thick photo-resist layer using a thermal bake process or an ultra-violet bake process.

19. The method of claim 17, wherein the low-topography region comprises a semiconductor layer having an edge adjacent to the high-topography region, further comprising patterning the thick photo-resist layer such that an edge of the thick photo-resist layer adjacent to the edge of the low-topography region is formed at a distance to ensure that a top surface of the anti-reflective layer is substantially parallel with a top surface of the semiconductor layer in a region overlying the semiconductor layer.

20. The method of claim 17, wherein the low-topography region comprises a semiconductor layer having an edge adjacent to the high-topography region, further comprising patterning the thick photo-resist layer such that an edge of the thick photo-resist layer adjacent to the edge of the low-topography region is formed at a distance to ensure that a top surface of the thin photo-resist layer is substantially parallel with a top surface of the semiconductor layer in a region overlying the semiconductor layer.
